(19) United States
(12) Patent Application Publication
(10) Pub. No.: US 2007/0224779 A1
(43) Pub. Date: Sep. 27, 2007

(54) Method for fabricating a BGA device and BGA device

(76) Inventor: Soo Gil Park, Radebeul (DE)

Correspondence Address: SLATER & MATSIL LLP, 17950 PRESTON ROAD, SUITE 1000, DALLAS, TX, 75252, US

(21) Appl. No.: 11/388,218

(22) Filed: Mar. 23, 2006

(51) Int. Cl. H01L 21/00

(52) U.S. Cl. 438/460

(57) ABSTRACT

In a method chips are provided with solder balls as of a ball grid array directly without any substrate thereby forming a BGA device. The inventive BGA device is protected on its active side by a protective layer made of solder resist or other equivalent materials and the solder balls on the contact pads of the die are suitable to be connected to an other assembly directly.

### TECHNICAL FIELD

The present invention relates generally to electronic components, and more particularly to a method for fabricating a BGA device and BGA device.

### BACKGROUND

One type of semiconductor package is referred to as a BGA package. A BGA package includes an area array of solder balls that permit the package to be surface mounted to the printed circuit board (PCB) or other electronic component. Conventional BGA packages are substrate-based and are provided with a substrate for receiving a chip. Two kinds of mounting a chip on the substrate are known: a wirebonded BGA package and a flip-chip BGA package.

Generally, in a wirebonded BGA package the chip is attached to the substrate by an adhesive layer, which is provided between the non active side of the chip and the upper side of the substrate. The lower side of the substrate is provided with solder balls for electrically connecting to an outer circuitry. The electrical connection between the chip and the substrate is made by bonding wires between bonding pads on the chip and bonding pads on the substrate.

In flip-chip BGA packages, the chip is mounted with its active surface facing the upper surface of the substrate. Between the bonding pads on the chip and bonding pads on the substrate are arranged solder balls for electric connection and mechanically fastening.

Both environments are usually encapsulated by a mold compound.

Conventionally, after grinding the wafer, backside chips are singulated on the wafer arrangement by dicing. After dicing the chips are picked up and mounted on a common substrate together with multiple other chips in the above-mentioned matter. After the molding process the singular devices are singulated by sawing along the device borders.

The conventional skip process comprises the steps of wafer backgrinding; wafer sawing; printing; die attaching; wire bonding or reflowing; molding; attaching solder balls on the lower side of the substrate; saw simulation; and test.

### SUMMARY OF THE INVENTION

Embodiments of the invention relate to a method for fabricating a semiconductor device. A semiconductor wafer, which includes semiconductor chips having an active side with first contact pads, is covered with a protective layer on its surface of the active side. Thereafter, the protective layer is removed from the first contact pads. The first contact pads are provided with connecting elements. The protective layer, on one hand, protects the active side of the chips. On the other hand, the protective layer leaves a window open in the area of the first contact pads and supports the adjustment of the connecting elements. The connecting elements are designed for substrateless mounting onto an outer assembly. The semiconductor device is substrateless completed by singulating the chips on the wafer by means of dicing.

Embodiments of the invention also relate to a semiconductor device that includes a die with an active side having first contact pads. The protective layer is arranged on the surface of the active side and is provided with windows in the area of the first contact pads. Thereby, the surface of the first contact pads is open. Connecting elements are arranged on the first contact pads. These connecting elements are formable for substrateless mounting the device onto an outer assembly.

Embodiments of the invention allow manufacturing a semiconductor device without a substrate. As a result, fewer production steps are necessary and most of the production steps can proceed at the wafer level.

The invention is to be explained in more detail below by exemplary embodiments.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 shows a semiconductor wafer with chips in front view;

FIG. 2 shows a detailed chip of the semiconductor wafer in FIG. 1 with a redistribution layer in front view;

FIG. 3 shows the chip of FIG. 2 in cross-section along line III-III in FIG. 2;

FIG. 4 shows the semiconductor wafer covered with solder resist on the active side in front view;

FIG. 5 shows a detailed chip of the semiconductor wafer of FIG. 4 with a solder resist layer in front view;

FIG. 6 shows the chip of FIG. 5 in cross-section along line VI-VI in FIG. 5;

FIG. 7 shows a first embodiment of the invention with the semiconductor wafer with an etched solder resist layer;

FIG. 8 shows a detailed chip of the semiconductor wafer of FIG. 7 with an etched solder resist layer;

FIG. 9 shows the chip of FIG. 8 in cross-section along line IX-IX in FIG. 8;

FIG. 10 shows the semiconductor wafer after applying solder paste and reflow in front view;

FIG. 11 shows a detailed chip of the semiconductor wafer of FIG. 10 in front view;

FIG. 12 shows the chip of FIG. 11 in cross-section along line XII-XII in FIG. 11;

FIG. 13 shows singulated dies on a supporting tape;

FIG. 14 shows a die of FIG. 13 in cross-section;

FIGS. 15a-15c show the procedure of mounting the die onto an outer assembly;

FIG. 16 shows a second embodiment of the invention with the semiconductor wafer with a polyamide layer on the backside of the semiconductor wafer;

FIG. 17 shows a detailed chip of the semiconductor wafer of FIG. 16 in front view;

FIG. 18 shows the chip of FIG. 17 in cross-section along line XVIII-XVIII in FIG. 17;

FIG. 19 shows a schematic picture of coating the chip backside with a polyamide layer 7;

FIG. 20 shows the semiconductor wafer of FIG. 16 in front view of the active side after applying solder paste and reflow;

FIG. 21 shows a chip of the semiconductor wafer in FIG. 20 in front view;

FIG. 22 shows the chip of FIG. 21 in cross-section along line XXII-XXII in FIG. 21;

FIG. 23 shows singulated dies on a supporting tape; and

FIG. 24 shows the die of FIG. 23 in cross-section.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

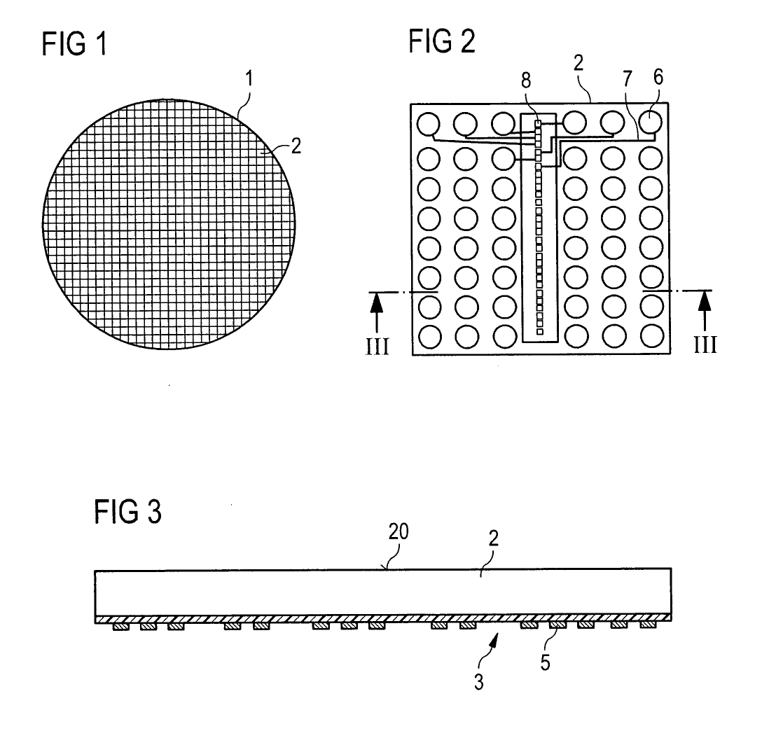

As shown in FIG. 1 a semiconductor wafer 1 includes multiple chips 2. A single chip 2 is shown in more detail in FIG. 2. The active side 3 of the chip 2 is the side where active functional elements of the chip 2, e.g., transistors, diodes, capacitors or the like (not shown), are arranged. The backside 20 typically includes no active circuitry. A cross-sectional view of the chips is shown in FIG. 3.

On its active side 3, the chip 2 is provided with a protective layer 4. A redistribution layer 5 is applied over the surface of the protective layer 4 opposite the chip 2. The protective layer 4 is preferably made of polyamide or a similar (e.g., equivalent material). Electrical connection between the redistribution layer 5 and the functional elements is made by connecting vias (not shown) through the protective layer 4. The redistribution layer 5 comprises first contact pads 6 and connecting lines 7 interconnecting the contact pads 6 with the contact areas 8 on the chip 2, as shown in FIG. 2.

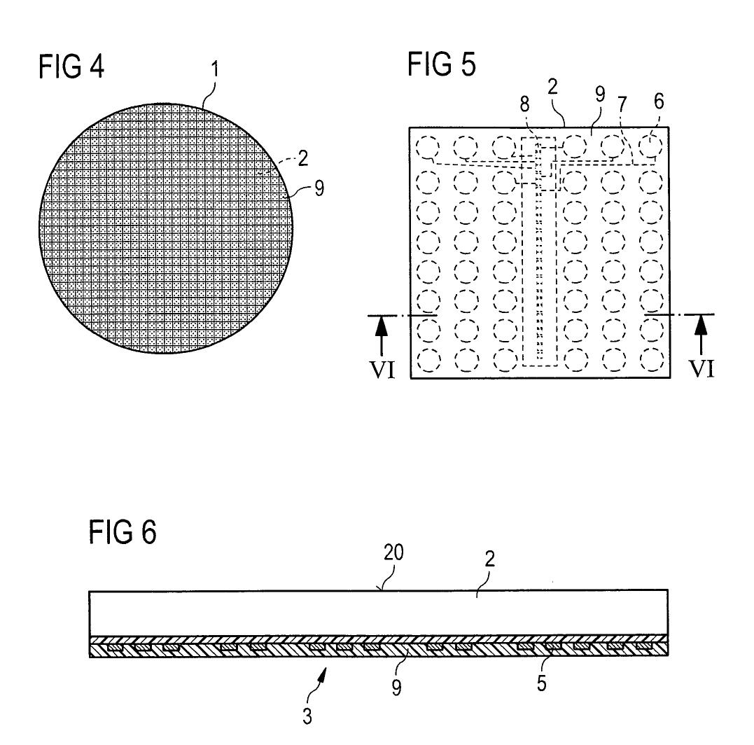

As depicted in FIG. 4, the semiconductor wafer 1 is covered with a solder resist layer 9 on the active side 3. The first contact pads 6 are covered by the solder resist layer 9 as shown in FIGS. 5 and 6. It is also possible to choose a material other than solder resist and to cover the semiconductor wafer 1. For instance, a pre-preg or equivalent material, can be used instead of the solder resist layer 9.

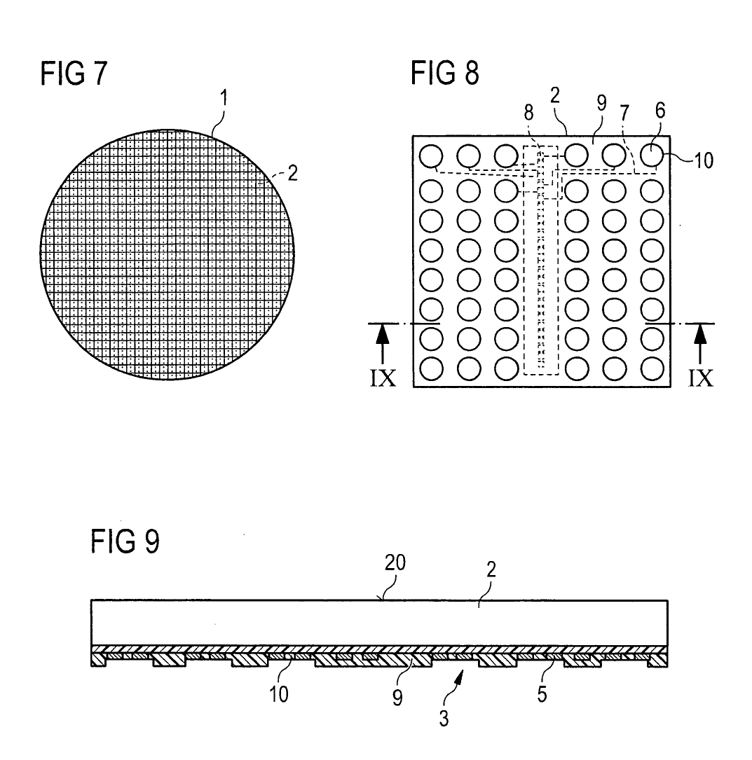

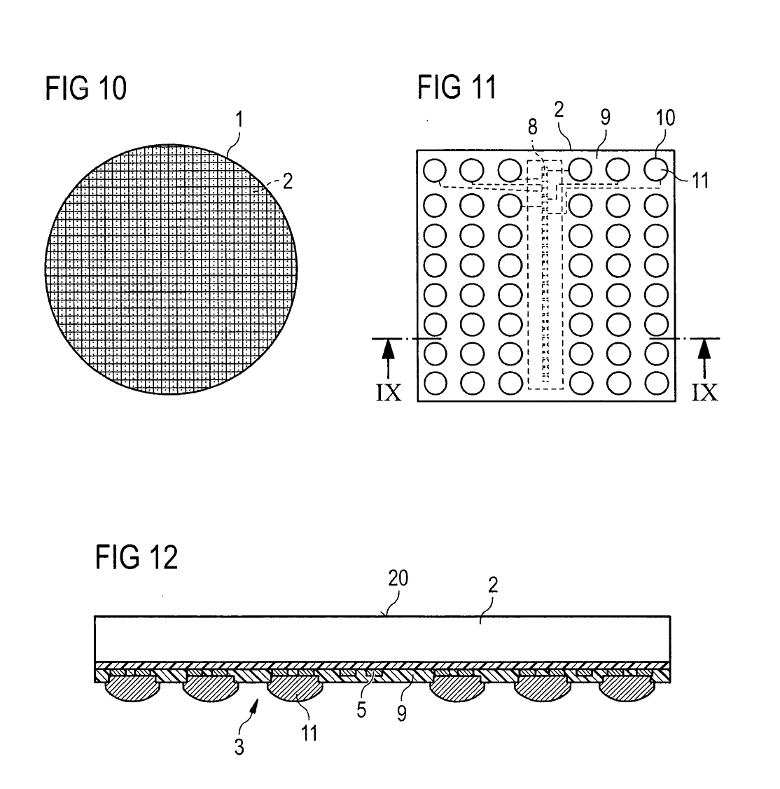

As shown in FIGS. 7 to 9, the solder resist layer a is etched in such a way that windows 10 expose the surface of the first contact pads 6. The rest of the surface of the active side 3 of the chip 2 remains covered by the solder resist layer 9. After making the windows 10 a solder paste is applied onto the active side 3 and thereafter a reflow process is executed to form solder balls 11 in the area of the windows 10. These solder balls are in the first contact pads 6. (See FIGS. 10 to 12.)

Thereafter, the semiconductor wafer 1 is diced by sawing along the borders of the chips 2. These singulated chips 2 can be referred to as dies. The dies 12 are picked from the wafer 1 and adhered to a supporting tape 22. The active side 3 of each die 12 is covered by the solder resist layer 9 except over the contact pads 6 where the solder balls 11 are located in the windows 10. The solder resist layer can, therefore, function as a first protective layer. Additionally, the protective layer 4 acts as a second protective layer. The other surfaces of the die 12 do not need to be covered with any layer, because the backside 13 and the sidewalls 14 are self-protected against any environment influence. In this state the BGA device is already completed for mounting on an outer assembly 15 as shown in FIG. 15, which includes FIGS. 15a-15c. The outer assembly 15 can be a printed circuit board 16 (PCB), as an example. The PCB 16 is provided with second contact pads 17, which are electrically connected with the contact lines of the PCB 16. The second contact pads 17 are arranged in a pattern corresponding to the pattern of the first contact pads 6, i.e., corresponding to the pattern of the ball grid array (BGA).

A solder paste 18 can also be applied to the second contact pads 17, as shown in FIG. 15a. As shown in FIG. 15b, an inventive BGA device 19 is adjusted corresponding to the PCB 16. As shown in FIG. 15c, the PCB 16 and the BGA device 19 are connected (electrically and physically) by a reflow process.

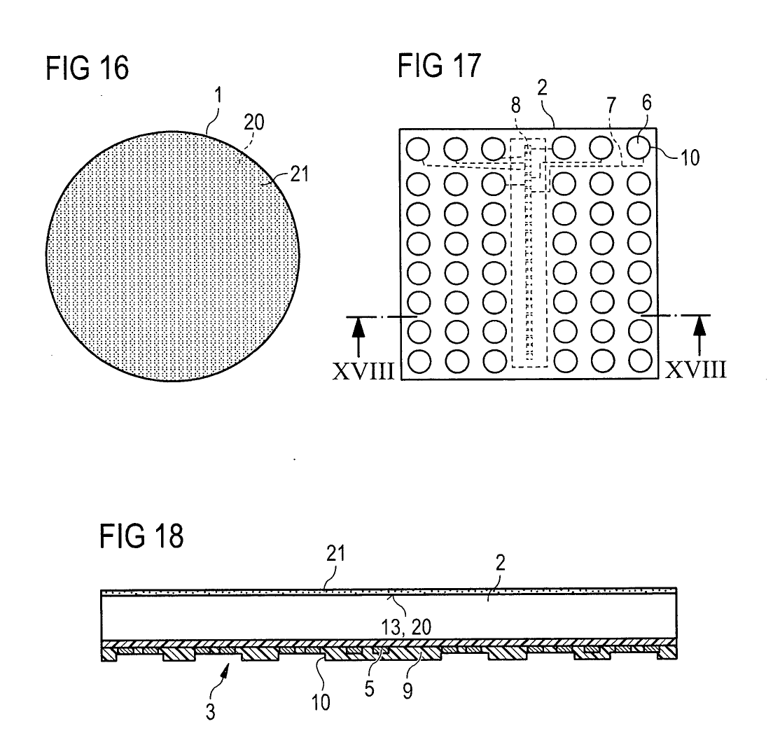

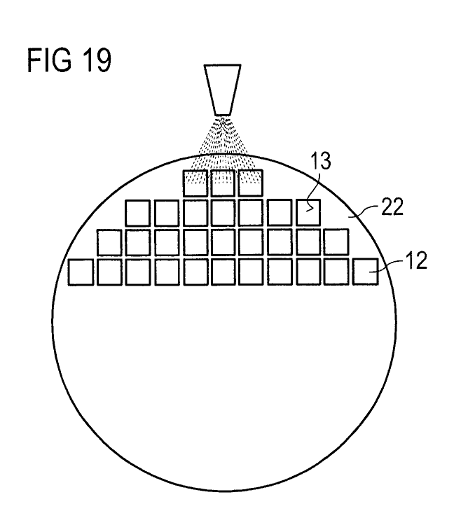

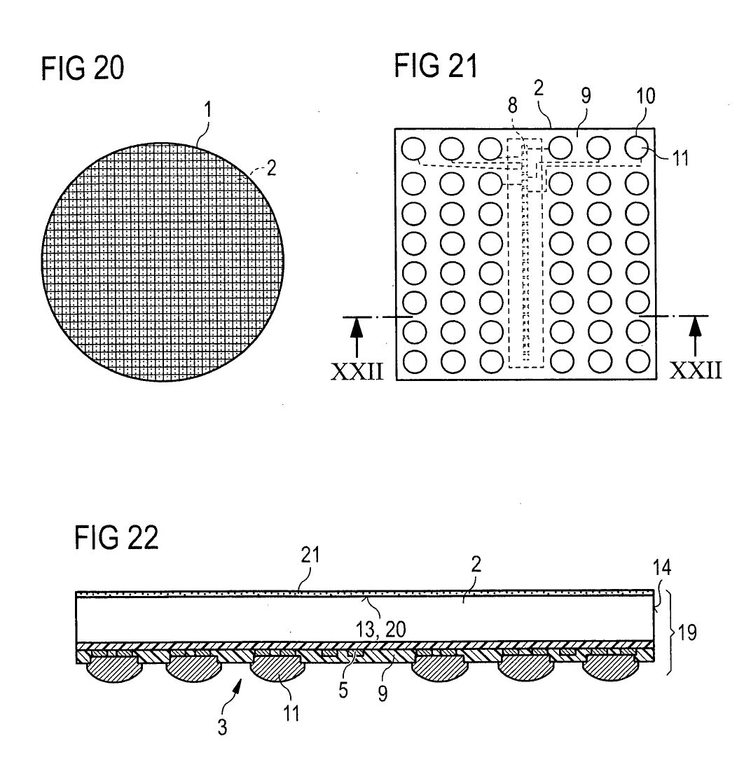

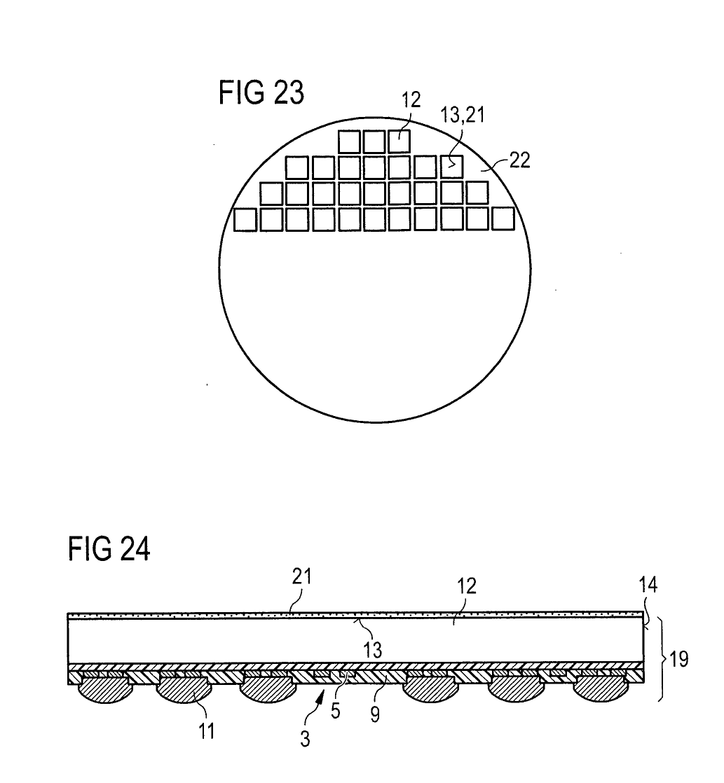

FIGS. 16 to 23 depict further embodiments of the invention. A stabilizing layer 21 of polyamide or of an equivalent material is applied on the backside 20 of the semiconductor wafer 1 after the steps shown in FIGS. 1 to 6. FIG. 19 shows a possibility for applying the stabilizing layer 21 alternatively to FIG. 16. In FIG. 16 the stabilizing layer 21 is applied onto the backside 20 of the semiconductor wafer 1 whereas in FIG. 19 the stabilizing layer 21 is applied onto the backside 13 of the dies 12. Preferably the stabilizing layer 21 is applied onto the backside 13 of the dies 12 by spraying.

The stabilizing layer 21 stabilizes the die 12 when the die 12 is very thin or of a large area because the die 12 is the BGA device 19 itself without any substrate.

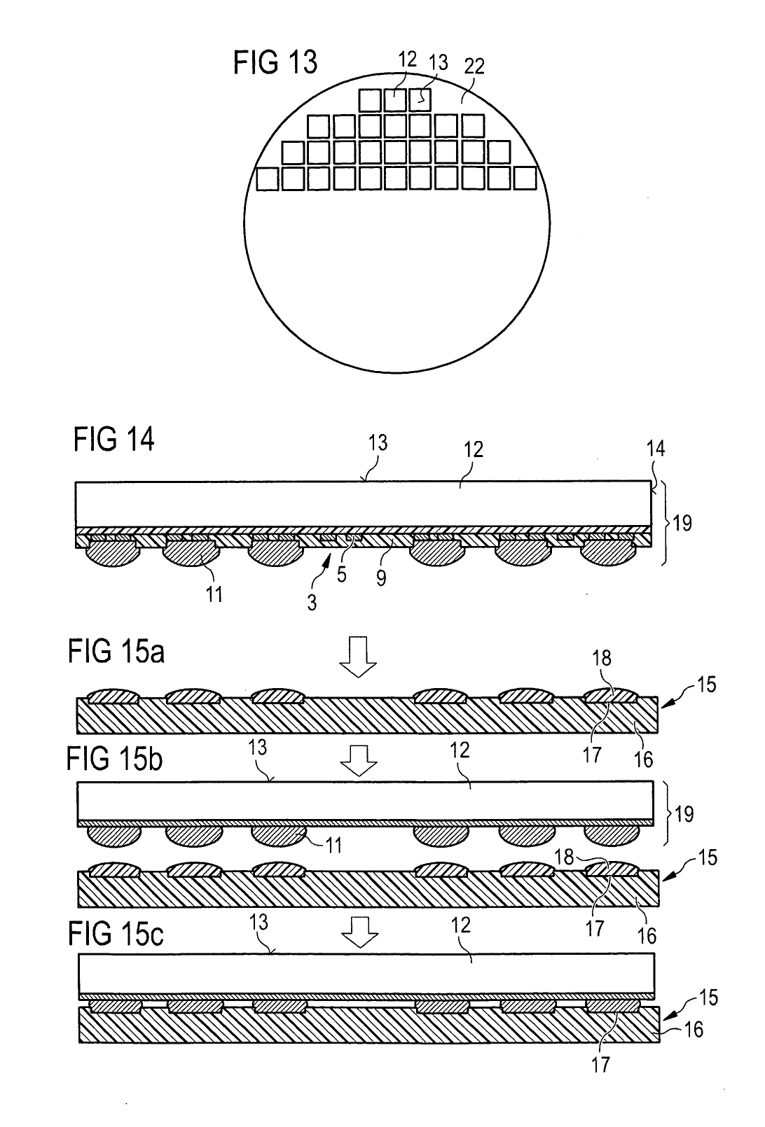

As shown in FIGS. 22 to 24, after covering the backside 20 of the wafer 1, chips 2 are singulated into dies 12 in a manner similar to those steps as shown in FIGS. 10 to 14. After singulating the BGA device 19 is completed.

In embodiments of this invention, the steps of providing a redistribution layer, making solder ball pads, and making solder balls occur on a wafer basis in a very productive manner. Only thereafter the dies are singulated. Conventional process steps, such as wafer backgrinding, wafer saw, printing, die attach, wire bonding, molding and solder ball attaching process, are prevented.

What is claimed is:

1. A method for fabricating a semiconductor device, the method comprising:
providing a semiconductor wafer having chips, each chip having an active side with first contact pads;
covering the active side with a protective layer;
removing the protective layer from the first contact pads;
providing the first contact pads with connecting elements; and
dicing the wafer into semiconductor devices.

2. The method of claim 1, further comprising mounting the semiconductor device onto an outer assembly, the mounting comprising:
providing the outer assembly that includes an upper surface with second contact pads in a pattern corresponding to the pattern of the first contact pads;
aligning a die so that the first contact pads provided with the connecting elements are in alignment with the second contact pads; and
mounting the die onto the outer assembly so that the first contact pads are in electrical contact with the second contact pads.

3. The method of claim 2, wherein providing the first contact pads with connecting elements comprises providing the first contact pads with solder balls, the method further comprising:
providing the second contact pads with solder paste before aligning the die so that the die is mounted onto the outer assembly by soldering the first and the second contact pads by reflowing the solder balls.

4. The method of claim 3 wherein covering the active side with a protective layer comprises covering the active side with a solder resist.

5. The method of claim 3, further comprising providing the upper surface of the outer assembly with a layer of solder resist not covering the second contact pads.

6. The method of claim 1, wherein covering the active side with the protective layer comprises covering the active side with a pre-preg material.

7. The method of claim 1, further comprising covering the backside of the wafer with a backside coating.

8. The method of claim 7, wherein the backside of the wafer is covered with the backside coating before dicing the wafer.

9. The method of claim 7, wherein the backside of the wafer is covered with the backside coating after dicing the wafer.

10. The method of claim 7, wherein the backside of the wafer is covered with polyamide.

11. The method of claim 7, wherein covering the backside of the wafer comprises covering the backside with a printable material by printing.

12. The method of claim 7, wherein covering the backside of the wafer comprises cover the backside with the sprayable material by spraying.

13. The method of claim 1, further comprising forming the first contact pads as parts of a redistribution layer between the active side of the die and the protective layer and providing a second protective layer between the redistribution layer and the die.

14. The method of claim 13, wherein the second protective layer comprises a polyamide material.

15. A semiconductor device comprising:
a die with an active side provided with first contact pads;
a protective layer over the active side of the die, the protective layer having windows in the area of the first contact pads; and
connecting elements arranged in the windows and in electrical contact with the first contact pads.

16. The semiconductor device of claim 15, wherein the connecting elements comprise solder balls.

17. The semiconductor device of claim 15, wherein the protective layer comprises solder resist.

18. The semiconductor device of claim 15, wherein the protective layer comprises polyamide.

19. The semiconductor device of claim 15, further comprising a redistribution layer arranged between the active side of the die and the protective layer, wherein the first contact pads are part of the redistribution layer.

20. The semiconductor device of claim 19, further comprising a second protective layer arranged between the redistribution layer and the die.
